(19) United States
(12) Patent Application Publication
(10) Pub. No.: US 2002/0000864 A1
(43) Pub. Date: Jan. 3, 2002

(54) SEMICONDUCTOR INTEGRATED CIRCUIT DEVICE USING SUBSTRATE BISING AND DEVICE CONTROL METHOD THEREOF

(76) Inventors: TETSUYA FUJITA, KAWASAKI-SHI (JP); TADAHIRO KURODA, KOTO-KU (JP)

Correspondence Address: HOGAN & HARTSON, L.L.P., BILTMORE TOWER, 500 SOURTH GRAND AVENUE,, SUITE 1900, LOS ANGELES, CA, 90071, US

(21) Appl. No.: 09/135,975

(22) Filed: Aug. 18, 1998

(30) Foreign Application Priority Data
Aug. 19, 1997 (JP) 222639/1997

(51) Int. Cl. H03L 5/00

(52) U.S. Cl. 327/318

(57) ABSTRACT

A back gate of a P-channel MOS transistor constituting a CMOS input protection circuit or a CMOS output protection circuit, is biased by a voltage higher than a peak voltage of overshoot of an input signal or an output signal, or a back gate of an N-channel MOS transistor constituting an input protection circuit or an output protection circuit, is biased by a voltage lower than a negative peak voltage of undershoot, thereby restricting a current inflow to a substrate from an I/O terminal that might cause a latch-up in the CMOS semiconductor integrated circuit.

### BACKGROUND OF THE INVENTION

The present invention relates generally to a semiconductor integrated circuit device and a control method thereof and, more particularly, to an input protection circuit and an output protection circuit in a CMOS semiconductor integrated circuit and a control method thereof.

FIG. 7 is a circuit diagram showing a conventional input protection circuit used in a CMOS semiconductor integrated circuit.

The input protection circuit in FIG. 7 is constructed of a P-channel MOS transistor MP in which a power source potential point V_{DD} is connected to a gate, a source and a substrate (back gate) thereof, and an input signal IN is supplied to a drain thereof, and of an N-channel MOS transistor MN in which a common potential point GND is connected to a gate, a source and a substrate (back gate), and the input signal IN is supplied to a drain thereof. The input protection circuit is connected via a buffer Buf to an internal circuit.

This input protection circuit, if the input signal IN having an excessively large amplitude is supplied, the P-channel MOS transistor M_{P} or the N-channel MOS transistor M_{N} is turned ON with the result that an electric current flows away to the power source potential point V_{DD} or the common potential point GND, thus performing a role of protecting a device constituting the internal circuit.

When an electric potential of the input signal IN is under the power source potential V_{DD}, both of the gate and the source of the P-channel MOS transistor M_{P} are connected to the power source potential point V_{DD}, and hence a gate/source voltage V_{GS} does not exceed a threshold voltage Vₜₕₚ. Consequently, no current flows across the P-channel MOS transistor M_{P}. If the potential of the input signal IN becomes higher than the power source potential V_{DD} due to overshoot, however, the source and the drain of the P-channel MOS transistor are replaced with each other in their relationship, and the gate/source voltage V_{GS} becomes a negative value under the threshold voltage Vₜₕₚ, in which case the P-channel MOS transistor M_{P} is turned ON and the current flows to the power source potential point V_{DD} connected to the drain from an input terminal IN connected to the source, thereby restricting a peak voltage of the overshoot.

When the potential of the input signal IN is over the common potential GND, the gate/source voltage V_{GS} does not exceed a threshold voltage Vthn because of the common potential point GND being connected to both of the gate and the source of the N-channel MOS transistor MN, and therefore no current flows to the N-channel MOS transistor M_{N}. If the potential of the input signal IN is lower than the common potential GND due to undershoot, however, the source and drain of the N-channel MOS transistor M_{N} are replaced with each other in their relationship, and the gate/source voltage V_{GS} becomes a positive value over the threshold value Vₜₕₙ, in which case the N-channel MOS transistor M_{N} is turned ON and the current flows to the input terminal IN connected to the source from the power source potential point V_{DD} connected to the drain, thereby restricting a peak voltage of the undershoot.

In the input protection circuit as shown in FIG. 7, the current transiently flows to a substrate and a well via a P_{N} junction between the source and the substrate (back gate) due to a delay time till the P-channel MOS transistor M_{P} or the N-channel MOS transistor M_{N} is turned ON since the input signal IN was supplied, or a current proportional to a source/drain current Ids flows to the substrate and the well after the P-channel MOS transistor M_{P} or the N-channel MOS transistor M_{N} has been turned ON. The current flowing across the substrate in the former state is the very current itself flowing through the PN junction in a forward direction from the source. The current flowing across the substrate in the latter state is a substrate current based on impact ionization, a magnitude of which is said to be on the order of 1/100 to 1/10000 of the source/drain current Ids. Problems inherent in the prior art input protection circuit in connection with the above currents will hereinafter be explained.

FIG. 8 is a sectional view showing a structure of the prior art input protection circuit shown in FIG. 1. Given herein is an example where a P-type substrate is provided with the above input protection circuit.

A P-type substrate 1 is provided with an N-type well 2, and an N⁺ region 3 and P⁺ regions 4, 5 are provided in the vicinity of an internal surface of the N-type well 2. Further, N⁺ regions 6, 7 and a P⁺ region 8 are provided in an area, outside the N-type well 2, of the P-type substrate 1. The P-channel MOS transistor M_{P} is constructed in such a way that the N⁺ region 3 serves as a substrate (back gate) B_{P}, the P region 4 serves as a source S_{P}, and the P⁺ region 5 serves as a drain D_{P}. The N-channel MOS transistor M_{N} is constructed in such a way that the N⁺ region 6 serves as a drain D_{N} the N⁺ region 7 serves as a source S_{N}, and the P⁺ region 8 serves as a substrate (back gate) B_{N}. A gate G_{P}, 9 is provided via an insulating layer on between the source and drain of the P-channel MOS transistor M_{P}, and a gate G_{N} 10 is provided via an insulating layer on between the source and drain of the N-channel MOS transistor M_{N}.

Then, as described above referring to FIG. 7, the power source potential point V_{DD} is connected to the gate GP9, the source S_{P}4 and the substrate (back gate) B_{P}3 of the P-channel MOS transistor M_{P}, and the input signal IN is supplied to the drain D_{P}5. Further, the common potential point GND is connected to the gate G_{N}10, the source S_{N}7 and the substrate (back gate) B_{N}8 of the N-channel MOS transistor M_{N}, and the input signal IN is supplied to the drain D_{N}6.

If the potential of the input signal IN becomes higher than the power source potential V_{DD} due to the overshoot, the source S_{P} and the drain D_{P} are replaced with each other in their relationship, and the gate/source voltage V_{GS} of the P-channel MOS transistor M_{P} becomes a negative value. Since there is a delay till the P-channel MOS transistor MP is turned ON since the input signal IN was supplied, the current flows to the N-type well 2 from the input terminal IN via the PN junction between the source SP5 and the substrate (back gate). Even when the gate/source voltage V_{GS} exceeds the threshold voltage Vₜₕₚ, and the P-channel MOS transistor is turned ON, it might happen that the current flows to the power source potential point V_{DD} connected to the drain DP4 from the input terminal IN, and that an electric current approximate to 1 mA flows to the N-type well 2 on the assumption that the source/drain current I_{ds} is on the order of, e.g., 100 mA.

In the P-channel MOS transistor MP constituting a parasitic PNP bipolar transistor, the P⁺ region 5 of the source S_{P} serves as an emitter, the N-type well 2 serves as a base, and a P-type substrate 1 serves as a collector. 1 The current having flowed to the N-type well 2 becomes a base current, and the current flows to between the collector and the emitter, i.e., between the P-type substrate 1 and the p⁺ region 5 (the source S_{P}, of the P-channel MOS transistor M_{P}). As a result, the potential of the P-type substrate 1 rises, and the current flows via the PN junction to between the P-type substrate 1 and the common potential point GND connected to the N⁺ region 7 of the source S_{N} of the N-channel MOS transistor M_{N}.

At this time, all the N-type wells 2 constituting the parasitic NPN bipolar transistor serve as a collector, the P-type substrate 1 serves as a base, and all the N⁺ regions 7 of the source SN of the N-channel MOS transistor M_{N} serve as an emitter. The current having flowed to the P-type substrate 1 becomes a base current, and the current flows to between the collector and the emitter, i.e., between all the N-type wells 2 and the N⁺ regions 7 (the source S_{N} of the N-channel MOS transistor M_{N}). Thus, the parasitic PNP bipolar transistor and the parasitic NPN bipolar transistor makes them turned ON each other, and, even if there is no overshoot as a trigger, a large current flows to between the power source potential point VDD and the common potential point GND with the result that the device is damaged all the more. This is a well-known latch-up.

Further, when the potential of the input signal IN is lower than the common potential GND due to the undershoot, the source S_{N} and the drain D_{N} are replaced with each other in their relationship, and the gate/source voltage V_{GS} of the N-channel MOS transistor M_{N} becomes a positive value. Since there is a delay till the N-channel MOS transistor M_{N} is turned ON, the current flows to the P-type substrate 1 via the PN junction between the source SN6 and the substrate (back gate). Even if the gate/source voltage VGS of the N-channel MOS transistor M_{N} exceeds the threshold voltage Vthn with the result that the N-channel MOS transistor M_{N} is turned ON, it might happen that the current flows to the input terminal IN connected to the source S_{N}6 from GND connected to the drain D_{N}7, and that the current approximate to 1 mA flows to the P-type substrate 1 on the assumption that the source/drain current I_{ds} is, e.g., 100 mA.

In the N-channel MOS transistor M_{P} constituting a parasitic NPN bipolar transistor, the N⁺ region 6 of the source S_{N} serves as an emitter, the P-type substrate 1 serves as a base, and the N-type well 2 serves as a collector. The current having flowed to the P-type substrate 1 becomes a base current, and the current flows to between the collector and the emitter, i.e., between the N-type well 2 and N⁺ region 6 (the source S_{N} of the N-channel MOS transistor M_{N}). As a result, the potential of the N-type well 2 decreases, and the current flows via the PN junction to between the N-type well 2 and the power source potential point connected to the P⁺ region 4 of the source S_{P} of the P-channel MOS transistor M_{P}. At this time, the P-type substrate 1 constituting the parasitic PNP bipolar transistor serves as a collector, the N-type well 2 serves as a base, and the P⁺ region 4 of the source S_{P} of the P-channel MOS transistor M_{P} serve as an emitter. The current having flowed to the N-type well becomes a base current, and the current flows to between the collector and the emitter, i.e., between the P-type substrate 1 and the P⁺ region 4. Thus, the parasitic NPN bipolar transistor and the parasitic PNP bipolar transistor makes them turned ON each other, and, as in the case of the overshoot, a large current flows to between the power source potential point V_{DD} and the common potential point GND in the case of the undershoot also. Unlike the case where the overshoot is the trigger for the latch-up, however, in the case of the undershoot, a period for which the parasitic NPN bipolar transistor is allowed to remain ON is limited to a duration of the undershoot occurred. Hence, when the undershoot as the trigger disappears, the current between the power source potential point V_{DD} and the common potential point GND also disappears.

As a conventional countermeasure against the problems described above, the latch-up is prevented by forming at a structurally short pitch a substrate contact for connecting the N-type well 2 to the power source potential point VDD and a substrate contact for connecting the P-type substrate 1 to the common potential point GND, promptly collecting the currents flowed to the substrate and the well at the common potential point GND and the power source potential point V_{DD} via the substrate contacts, and thus restricting fluctuations in the potentials of the substrate and of the well.

In conventional countermeasure, however, though effective in the case where the potentials of the substrate and the well are supplied at a low output impedance as in the case of the power source such as the power source potential point V_{DD} and the common potential point GND, has a problem in which an area of a charge pump circuit is required to be taken large in terms of a constraint by the output impedance of the charge pump circuit in such a case as to bias the substrate using the charge pump circuit. Note that the input protection circuit has been described so far, however, an output protection circuit also presented the same problems.

### SUMMARY OF THE INVENTION

It is a first object of the present invention to provide a semiconductor integrated circuit device capable of restricting a current inflow into a substrate from I/O terminals, which is a cause of a latch-up of an input protection circuit and an output protection circuit in a CMOS semiconductor integrated circuit.

It is a second object of the present invention to provide a method of controlling a semiconductor integrated circuit device.

According to one aspect of the present invention, there is provided a semiconductor integrated circuit device comprising: a CMOS-based input protection circuit or a CMOS-based output protection circuit constructed of a pair of a P-channel MOS transistor and an N-channel MOS transistor, wherein a back gate of said P-channel MOS transistor is biased at a voltage higher than a peak voltage of an overshooting input or output signal of said P-channel MOS transistor, or a back gate of said N-channel MOS transistor is biased at a voltage lower than a negative peak voltage of undershooting input or output signal of said N-channel MOS transistor.

According to an another aspect of the present invention, there is provided a method of controlling a semiconductor integrated circuit device having a CMOS-based input protection circuit or a CMOS-based output protection circuit constructed of a pair of a P-channel MOS transistor and an N-channel MOS transistor, said method comprising: a step of biasing the back gate of said P-channel MOS transistor at a voltage higher than a peak voltage of an overshooting of an input signal or an output signal of said P-channel MOS transistor, or biasing a back gate of said N-channel MOS transistor at a voltage lower than a negative peak voltage of an undershooting of the input signal or the output signal.

The semiconductor integrated circuit device and the control method thereof according to the present invention are characterized by restricting the current inflow into the substrate from the I/O signals which has hitherto been the cause of the latch-up, which involves, in an I/O cell of a CMOS semiconductor integrated circuit device, applying a voltage higher than a peak voltage of overshoot of the input signal or the output signal to a back gate (N-type substrate or N-type well) of a P-channel MOS transistor constituting an input protection circuit or an output protection circuit, or applying a voltage lower than a negative peak voltage of undershoot to a back gate (P-type substrate or P-type well) of an N-channel MOS transistor constituting an input protection circuit or an output protection circuit. This construction exhibits the greatest effect in stabilizing the potentials of the substrate and of the well, and it is feasible to largely reduce a possibility of causing the latch-up which has hitherto been treated as the problem in all CMOS circuits.

### BRIEF DESCRIPTION OF THE DRAWINGS

FIG. 1 is a circuit diagram showing a semiconductor integrated circuit device (input protection circuit) in a first embodiment of the present invention;

FIG. 2 is a circuit diagram showing the semiconductor integrated circuit device (input protection circuit) in a second embodiment of the present invention;

FIG. 3 is a circuit diagram showing the semiconductor integrated circuit device (input protection circuit) in a third embodiment of the present invention;

FIG. 4 is a circuit diagram showing a semiconductor integrated circuit device (output protection circuit) in a fourth embodiment of the present invention;

FIG. 5 is a circuit diagram showing the semiconductor integrated circuit device (output protection circuit) in a fifth embodiment of the present invention; and

FIG. 6 is a circuit diagram showing the semiconductor integrated circuit device (output protection circuit) in a sixth embodiment of the present invention.

FIG. 7 is a circuit diagram showing a conventional input protection circuit;

FIG. 8 is a sectional view showing a structure of the conventional input protection circuit;

### DESCRIPTION OF THE PREFERRED EMBODIMENTS

Embodiments of a semiconductor integrated circuit device and a control method thereof will hereinafter be described with reference to the accompanying drawings.

FIG. 1 is a circuit diagram showing a semiconductor integrated circuit device which is, to be more specific, an input protection circuit in a first embodiment of the present invention.

The input protection circuit in the first embodiment of the present invention is constructed of a P-cannel MOS transistor MP in which a power source potential point V_{DD} is connected to a gate and a source thereof, an N-type substrate or an N-type well defined as a substrate (back gate) is previously biased by a voltage V_{SUB+}(V_{SUB+}>VIN_{Peak}+≧V_{DD}) higher than a peak voltage of a predicted overshoot of an input signal IN, and the input signal IN is supplied to a drain thereof, and of an N-channel MOS transistor M_{N} in which a common potential point GND is connected to a gate, a source and a substrate (back gate) thereof, and the input signal IN is supplied to its drain. The input protection circuit is connected via a buffer Buf to an internal circuit.

A power source for biasing the substrate may be either a power source the power of which is suppled from outside or a self-supplied power source with a charge pump circuit mounted in the semiconductor integrated circuit device.

In the input protection circuit in the first embodiment of the present invention, even if the source and the drain are replaced with each other in their relationship because of the potential of the input signal IN becoming higher than the power source potential V_{DD} due to the overshoot, the voltage V_{SUB+} higher than the peak voltage of the previously predicted overshoot is applied to the substrate (back gate) of the P-channel MOS transistor M_{P}, and hence it never happens that a PN junction between the source or the drain and the substrate (back gate) of the P-channel MOS transistor MP is biased in a forward direction. According to the prior art construction, there is a possibility in which the electric current flows into the substrate and the well via the PN junction. In the input protection circuit in the first embodiment of the present invention, however, the possibility described above is eliminated by the above construction.

A gate/source voltage V_{GS} of the P-channel MOS transistor MP becomes a negative value under a threshold value Vₜₕₙ with the result that the P-channel MOS transistor MP is turned ON, in which case the current flows to the power source potential pint V_{DD} connected to the drain through the input terminal IN connected to the source. In the input protection circuit in accordance with the first embodiment of the present invention, however, if it is assumed that a source/drain current Ids at that time is, e.g., 100 mA, only the current on the order of 1 mA may be conceived as a substrate current.

If the substrate current is on the order of 1 mA, the power source for biasing the substrate can be easily ensured regardless of whether the power source may be the power source supplied with the power from outside or the self-supplied power source with the charge pump circuit mounted in the semiconductor integrated circuit device.

In the input protection circuit in accordance with the first embodiment of the present invention, it is feasible to largely reduce a possibility of causing a latch-up that has hitherto been treated as a problem in all the conventional CMOS circuits by restricting the substrate current.

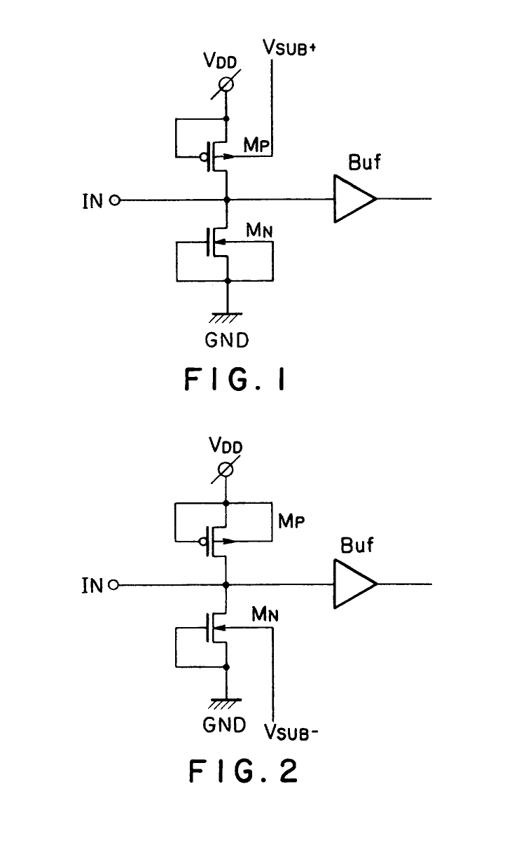

FIG. 2 is a circuit diagram showing a semiconductor integrated circuit device which is, to be more specific, an input protection circuit in a first embodiment of the present invention.

The input protection circuit in the second embodiment of the present invention is constructed of a P-cannel MOS transistor MP in which a power source potential point V_{DD} is connected to a gate, a source and a substrate thereof, and of an N-channel MOS transistor M_{N} in which a common potential point GND is connected to a gate and a source thereof, a P-type substrate or a P-type well defined as a substrate (back gate) is previously biased by a voltage V_{SUB-}(V_{SUB-}<VIN_{Peak-}≦GND) lower than a negative peak voltage of a predicted undershoot of an input signal IN, and the input signal IN is supplied to a drain thereof. The input protection circuit is connected via a buffer Buf to an internal circuit.

A power source for biasing the substrate may be either a power source supplied with power from outside or a self-supplied power source with a charge pump circuit mounted in the semiconductor integrated circuit device.

In the input protection circuit in the second embodiment of the present invention, even if the source and the drain are replaced with each other in their relationship because of the potential of the input signal IN becoming lower than the common potential GND due to the undershoot, the voltage V_{SUB-} lower than the peak voltage of the previously predicted undershoot is applied to the substrate (back gate) of the N-channel MOS transistor M_{N}, and hence it never happens that a PN junction between the source or the drain and the substrate (back gate) of the N-channel MOS transistor M_{N} is biased in the forward direction. According to the prior art construction, there is a possibility in which the electric current flows into the substrate and the well via the PN junction. In the input protection circuit in the first embodiment of the present invention, however, the possibility described above is eliminated by the above construction.

A gate/source voltage V_{GS} of the N-channel MOS transistor M_{N} exceeds the threshold value Vₜₕₙ with the result that the N-channel MOS transistor M_{N} is turned ON, in which case the current flows to the input terminal IN connected to the source from the common potential point GND connected to the drain. In the input protection circuit in accordance with the second embodiment of the present invention, however, if it is assumed that a source/drain current Ids at that time is, e.g., 100 mA, only the current on the order of 1 mA may be conceived as a substrate current.

If the substrate current is on the order of 1 mA, the power source for biasing the substrate can be easily ensured regardless of whether the power source may be the power source supplied with the power from outside or the self-supplied power source with the charge pump circuit mounted in the semiconductor integrated circuit device.

In the input protection circuit in accordance with the second embodiment of the present invention, it is feasible to largely reduce the possibility of causing the latch-up that has hitherto been treated as the problem in all the conventional CMOS circuits by restricting the substrate current.

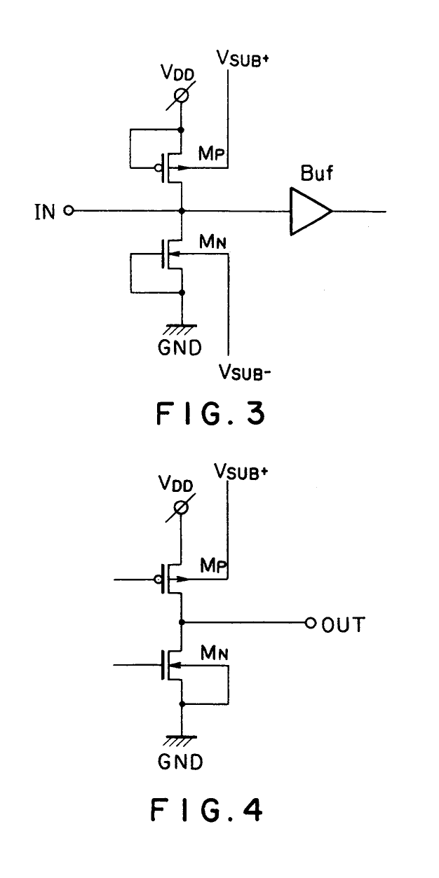

FIG. 3 is a circuit diagram showing a semiconductor integrated circuit device which is, to be more specific, an input protection circuit in a third embodiment of the present invention.

The input protection circuit in the third embodiment of the present invention is constructed of a P-cannel MOS transistor MP in which a power source potential point VDD is connected to a gate and a source thereof, an N-type substrate or an N-type well defined as a substrate (back gate) is previously biased by a voltage V_{SUB+}(V_{SUB+}>VIN_{Peak}+≧V_{DD})) higher than a peak voltage of a predicted overshoot of an input signal IN, and the input signal IN is supplied to a drain thereof, and of an N-channel MOS transistor M_{N} in which a common potential point GND is connected to a gate and a source thereof, a P-type substrate or a P-type well defined as a substrate (back gate) is previously biased by a voltage V_{SUB-}(V._{SUB-}<VIN_{Pead-}≦GND) lower than a negative peak voltage of a predicted undershoot of an input signal IN, and the input signal IN is supplied to a drain thereof. The input protection circuit is connected via a buffer Buf to an internal circuit.

A power source for biasing the substrate may be either a power source the power of which is suppled from outside or a self-supplied power source with a charge pump circuit mounted in the semiconductor integrated circuit device.

In the input protection circuit in the third embodiment of the present invention, even if the source and the drain are replaced with each other in their relationship because of the potential of the input signal IN becoming higher than the power source potential V_{DD} due to the overshoot, the voltage V_{SUB+} higher than the peak voltage of the previously predicted overshoot is applied to the substrate (back gate) of the P-channel MOS transistor M_{P}, and hence it never happens that a PN junction between the source or the drain and the substrate (back gate) of the P-channel MOS transistor M_{P} is biased in the forward direction. According to the prior art construction, there is a possibility in which the electric current flows into the substrate and the well via the PN junction. In the input protection circuit in the third embodiment of the present invention, however, the possibility described above is eliminated by the above construction.

A gate/source voltage V_{GS} of the P-channel MOS transistor M_{P} becomes a negative value under a threshold value Vₜₕₙ with the result that the P-channel MOS transistor M_{P} is turned ON, in which case the current flows to the power source potential pint V_{DD} connected to the drain through the input terminal IN connected to the source. In the input protection circuit in accordance with the third embodiment of the present invention, however, if it is assumed that a source/drain current Ids at that time is, e.g., 100 mA, only the current on the order of 1 mA may be conceived as a substrate current.

While on the other hand, even if the potential of the input signal IN is lower than the common potential GND due to the undershoot, the voltage V_{SUB-} lower than the peak voltage of the previously predicted undershoot is applied to the substrate (back gate) of the N-channel MOS transistor M_{N}. It therefore never happens that a PN junction between the source or the drain and the substrate (back gate) of the N-channel MOS transistor M_{N} is biased in the forward direction. According to the prior art construction, there is a possibility in which the electric current flows into the substrate and the well via the PN junction. In the input protection circuit in the third embodiment of the present invention, however, the possibility described above is eliminated by the above construction.

A gate/source voltage V_{GS} of the N-channel MOS transistor M_{N} exceeds the threshold value Vthn with the result that the N-channel MOS transistor M_{N} is turned ON, in which case the current flows to the input terminal IN connected to the source from the common potential point GND. In the input protection circuit in accordance with the third embodiment of the present invention, however, if it is assumed that a source/drain current I_{ds} at that time is, e.g., 100 mA, only the current on the order of 1 mA may be conceived as a substrate current.

If the substrate current is on the order of 1 mA, the power source for biasing the substrate can be easily ensured regardless of whether the power source may be the power source supplied with the power from outside or the self-supplied power source with the charge pump circuit mounted in the semiconductor integrated circuit device.

In the input protection circuit in accordance with the third embodiment of the present invention, the substrate current can be restricted in both cases of the overshoot and the undershoot of the input signal IN, and hence there is the greatest effect in stabilizing the potentials of the substrate and of the well. It is also feasible to largely reduce a possibility of causing a latch-up that has hitherto been treated as a problem in all the conventional CMOS circuits. FIG. 4 is a circuit diagram showing a semiconductor integrated circuit device which is, to be more specific, an output protection circuit in a fourth embodiment of the present invention.

The output protection circuit in the fourth embodiment of the present invention is a circuit to which the construction of the input protection circuit in the first embodiment of the present invention is applied. The output protection circuit in the fourth embodiment of the present invention is constructed of a P-cannel MOS transistor M_{P} in which a power source potential point V_{DD} is connected to a source thereof, an output terminal OUT is connected to a drain thereof, an N-type substrate or an N-type well defined as a substrate (back gate) is previously biased by a voltage V_{SUB+}(V_{SUB+}>VIN_{Peak}+≧V_{DD}) higher than a peak voltage of a predicted overshoot from the output terminal OUT, and of an N-channel MOS transistor M_{N} in which a common potential point GND is connected to a source and a substrate (back gate) thereof, and the output terminal OUT is connected to a drain thereof. A signal from an internal circuit is supplied to gates of the P- and N-channel MOS transistors M_{P} and M_{N}.

A power source for biasing the substrate may be either a power source the power of which is suppled from outside or a self-supplied power source with a charge pump circuit mounted in the semiconductor integrated circuit device.

In the output protection circuit in the fourth embodiment of the present invention, even if the source and the drain are replaced with each other in their relationship because of the potential at the output terminal OUT becoming higher than the power source potential V_{DD} due to the overshoot, the voltage V_{SUB+} higher than the peak voltage of the previously predicted overshoot is applied to the substrate (back gate) of the P-channel MOS transistor M_{P}, and hence it never happens that a PN junction between the source or the drain and the substrate (back gate) of the P-channel MOS transistor M_{P} is biased in the forward direction. According to the prior art construction, there is a possibility in which the electric current flows into the substrate and the well via the PN junction. In the output protection circuit in the fourth embodiment of the present invention, however, the possibility described above is eliminated by the above construction.

A gate/source voltage V_{GS} of the P-channel MOS transistor M_{P} becomes a negative value under a threshold value Vthn with the result that the P-channel MOS transistor M_{P} is turned ON, in which case the current flows to the power source potential pint V_{DD} connected to the drain through the output terminal OUT connected to the source. In the output protection circuit in accordance with the fourth embodiment of the present invention, however, if it is assumed that a source/drain current Ids at that time is, e.g., 100 mA, only the current on the order of 1 mA may be conceived as a substrate current.

If the substrate current is on the order of 1 mA, the power source for biasing the substrate can be easily ensured regardless of whether the power source may be the power source supplied with the power from outside or the self-supplied power source with the charge pump circuit mounted in the semiconductor integrated circuit device.

In the output protection circuit in accordance with the fourth embodiment of the present invention, it is feasible to largely reduce a possibility of causing a latch-up that has hitherto been treated as a problem in all the conventional CMOS circuits by restricting the substrate current.

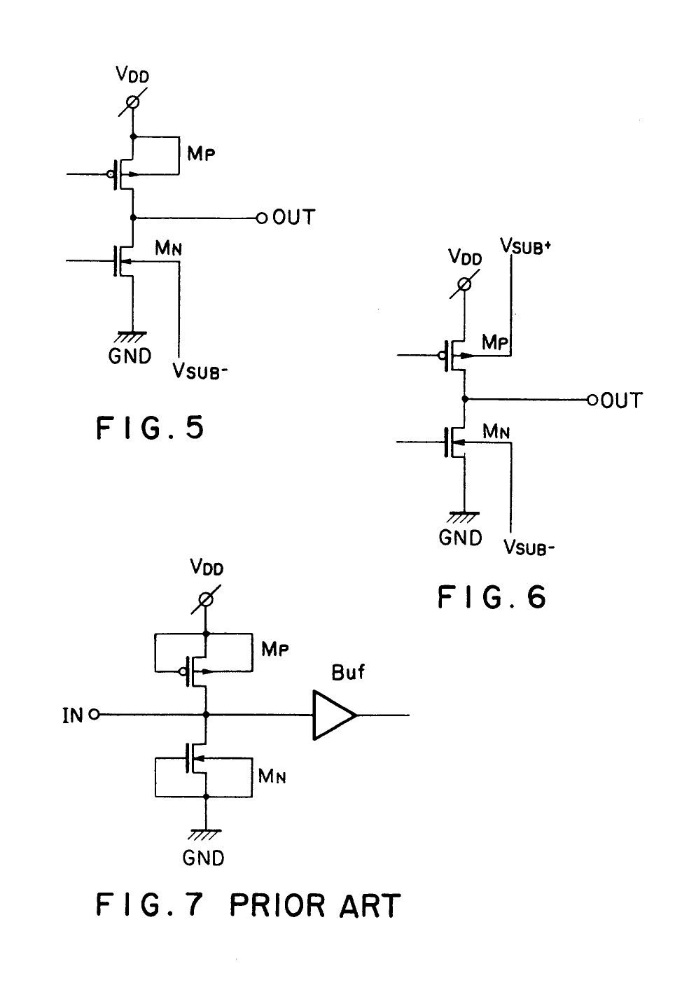

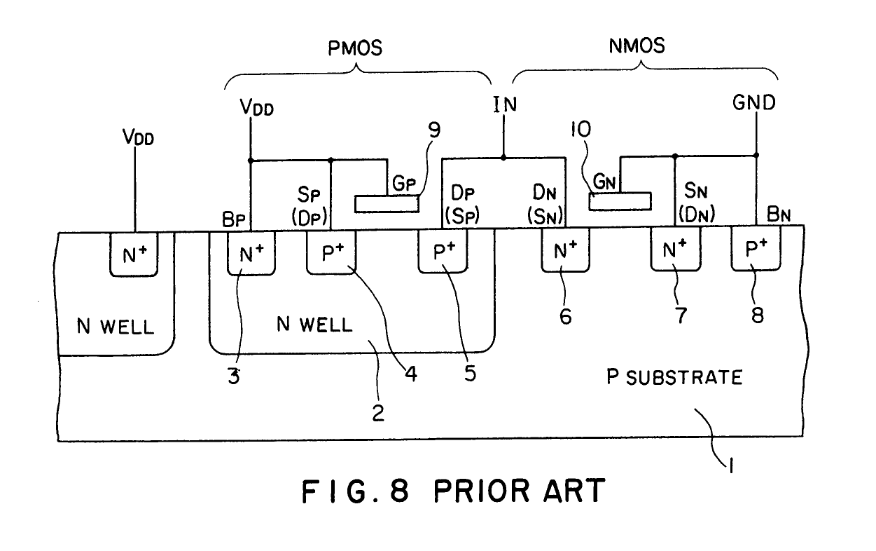

FIG. 5 is a circuit diagram showing a semiconductor integrated circuit device which is, to be more specific, an output protection circuit in a fifth embodiment of the present invention.

The output protection circuit in the fifth embodiment of the present invention is a circuit to which the construction of the input protection circuit in the second embodiment of the present invention is applied. The output protection circuit in the fifth embodiment of the present invention is constructed of a P-cannel MOS transistor M_{P} in which a power source potential point V_{DD} is connected to a source and a substrate (back gate) thereof, and an output terminal OUT is connected to a drain thereof, and an N-channel MOS transistor M_{N} in which a common potential point GND is connected to a source thereof, an output terminal OUT is connected to a drain thereof, and a P-type substrate or a P-type well defined as a substrate (back gate) is previously biased by a voltage V_{SUB-}(V_{SUB-}<VIN_{Peak-}≦GND) lower than a negative peak voltage of a predicted undershoot from the output terminal OUT. A signal from an internal circuit is supplied to gates of the P- and N-channel MOS transistors M_{P} and M_{N}.

A power source for biasing the substrate may be either a power source the power of which is suppled from outside or a self-supplied power source with a charge pump circuit mounted in the semiconductor integrated circuit device.

In the output protection circuit in the fifth embodiment of the present invention, even if the source and the drain are replaced with each other in their relationship because of the potential at the output terminal OUT becoming lower than the common potential GND due to the undershoot, the voltage V_{SUB-} lower than the peak voltage of the previously predicted undershoot is applied to the substrate (back gate) of the N-channel MOS transistor M_{N}, and hence it never happens that a PN junction between the source or the drain and the substrate (back gate) of the N-channel MOS transistor M_{N} is biased in the forward direction. According to the prior art construction, there is a possibility in which the electric current flows into the substrate and the well via the PN junction. In the output protection circuit in the fifth embodiment of the present invention, however, the possibility described above is eliminated by the above construction.

A gate/source voltage V_{GS} of the N-channel MOS transistor M_{N} exceeds a threshold value Vₜₕₙ with the result that the N-channel MOS transistor M_{N} is turned ON, in which case the current flows to the output terminal OUT connected to the source from the common potential point GND connected to the drain. In the output protection circuit in accordance with the fifth embodiment of the present invention, however, if it is assumed that a source/drain current Ids at that time is, e.g., 100 mA, only the current on the order of 1 mA may be conceived as a substrate current.

If the substrate current is on the order of 1 mA, the power source for biasing the substrate can be easily ensured regardless of whether the power source may be the power source supplied with the power from outside or the self-supplied power source with the charge pump circuit mounted in the semiconductor integrated circuit device.

In the output protection circuit in accordance with the fifth embodiment of the present invention, it is feasible to largely reduce a possibility of causing a latch-up that has hitherto been treated as a problem in all the conventional CMOS circuits by restricting the substrate current.

FIG. 6 is a circuit diagram showing a semiconductor integrated circuit device which is, to be more specific, an output protection circuit in a sixth embodiment of the present invention.

The output protection circuit in the sixth embodiment of the present invention is a circuit to which the construction of the input protection circuit in the third embodiment of the present invention is applied. The output protection circuit in the sixth embodiment of the present invention is constructed of a P-cannel MOS transistor MP in which a power source potential point V_{DD} is connected to a source thereof, an output terminal OUT is connected to a drain thereof, an N-type substrate or an N-type well defined as a substrate (back gate) is previously biased by a voltage V_{SUB+}(V_{SUB+}>VIN_{Peak+}≧V_{DD}) higher than a peak voltage of a predicted overshoot from the output terminal OUT, and an N-channel MOS transistor MN in which a common potential point GND is connected to a source thereof, an output terminal OUT is connected to a drain thereof, and a P-type substrate or a P-type well defined as a substrate (back gate) is previously biased by a voltage V_{SUB-}(V_{SUB-}<VIN_{Peak-}≦GND) lower than a negative peak voltage of a predicted undershoot from the output terminal OUT. A signal from an internal circuit is supplied to gates of the P- and N-channel MOS transistors M_{P} and M_{N}.

A power source for biasing the substrate may be either a power source the power of which is suppled from outside or a self-supplied power source with a charge pump circuit mounted in the semiconductor integrated circuit device.

In the output protection circuit in the sixth embodiment of the present invention, even if the source and the drain are replaced with each other in their relationship because of the potential at the output terminal OUT becoming higher than the power source potential VDD due to the overshoot, the voltage VSUB+ higher than the peak voltage of the previously predicted overshoot is applied to the substrate (back gate) of the P-channel MOS transistor M_{N}, and hence it never happens that a PN junction between the source or the drain and the substrate (back gate) of the P-channel MOS transistor M_{P} is biased in the forward direction. According to the prior art construction, there is a possibility in which the electric current flows into the substrate and the well via the PN junction. In the output protection circuit in the sixth embodiment of the present invention, however, the possibility described above is eliminated by the above construction.

A gate/source voltage VGS of the P-channel MOS transistor M_{P} becomes a negative value under a threshold value Vₜₕₙ with the result that the P-channel MOS transistor M_{P} is turned ON, in which case the current flows to the power source potential point V_{DD} connected to the drain from the output terminal OUT connected to the source. In the output protection circuit in accordance with the sixth embodiment of the present invention, however, if it is assumed that a source/drain current Ids at that time is, e.g., 100 mA, only the current on the order of 1 mA may be conceived as a substrate current.

While on the other hand, even if the potential at the output terminal OUT is lower than the common potential GND due to the undershoot, the voltage VSUB− lower than the peak voltage of the previously predicted undershoot is applied to the substrate (back gate) of the N-channel MOS transistor M_{N}. It therefore never happens that a PN junction between the source or the drain and the substrate (back gate) of the N-channel MOS transistor M_{N} is biased in the forward direction. According to the prior art construction, there is a possibility in which the electric current flows into the substrate and the well via the PN junction. In the output protection circuit in the sixth embodiment of the present invention, however, the possibility described above is eliminated by the above construction.

A gate/source voltage V_{GS} of the N-channel MOS transistor M_{N} exceeds the threshold value Vₜₕₙ with the result that the N-channel MOS transistor M_{N} is turned ON, in which case the current flows to the output terminal OUT connected to the source from the common potential point GND. In the output protection circuit in accordance with the sixth embodiment of the present invention, however, if it is assumed that a source/drain current Ids at that time is, e.g., 100 mA, only the current on the order of 1 mA may be conceived as a substrate current.

If the substrate current is on the order of 1 mA, the power source for biasing the substrate can be easily ensured regardless of whether the power source may be the power source supplied with the power from outside or the self-supplied power source with the charge pump circuit mounted in the semiconductor integrated circuit device.

In the output protection circuit in accordance with the sixth embodiment of the present invention, the substrate current can be restricted in both cases of the overshoot and the undershoot from the output terminal OUT, and hence there is the greatest effect in stabilizing the potentials of the substrate and of the well. It is also feasible to largely reduce a possibility of causing a latch-up that has hitherto been treated as a problem in all the conventional CMOS circuits.

A method of controlling the semiconductor integrated circuit device according to the present invention, as discussed in each embodiment of the semiconductor integrated circuit device of the present invention, the back gate of the P-channel MOS transistor MP constituting the input protection circuit using CMOS, is biased by the voltage higher than the peak voltage of the predicted overshoot of the input signal, or the back gate of the N-channel MOS transistor MN is biased by the voltage lower than the negative peak voltage of the predicted undershoot of the input signal, or the back gate of the P-channel MOS transistor constituting the output protection circuit using CMOS, is biased by the voltage higher than the peak voltage of the predicted overshoot from the output terminal, or the back gate of the N-channel MOS transistor is biased by the voltage lower than the negative peak voltage of the predicted undershoot from the output terminal.

According to the method of controlling the semiconductor integrated circuit device of the present invention, the same effects as those described in the respective embodiments of the semiconductor integrated circuit device of the present invention can be obtained.

According to the semiconductor integrated circuit device and the control method thereof of the present invention, the back gate (the N-type substrate or well) of the P-channel MOS transistor constituting the input protection circuit or the output protection circuit using CMOS, is biased by the voltage higher then the peak voltage of the overshoot of the input signal or the output signal, or the back gate (the P-type substrate or well) of the N-channel MOS transistor constituting the input protection circuit or the output protection circuit,. is biased by the voltage lower then the negative peak voltage of the undershoot. Therefore, the substrate current is restricted, and, as a result, it is possible to largely reduce the possibility of causing the latch-up that has hitherto been treated as the problem in all the CMOS circuits.

The back gate (the N-type substrate or well) of the P-channel MOS transistor constituting the input protection circuit or the output protection circuit using CMOS, is biased by the voltage higher then the peak voltage of the overshoot of the input signal or the output signal, and the back gate (the P-type substrate or well) of the N-channel MOS transistor constituting the input protection circuit or the output protection circuit, is biased by the voltage lower then the negative peak voltage of the undershoot. In this case, the substrate current can be restricted in both of the cases of the overshoot and the undershoot of the input signal or the output signal, and hence there is the greatest effect in stabilizing the potentials of the substrate and of the well. It is also feasible to largely reduce the possibility of causing the latch-up that has hitherto been treated as the problem in all the CMOS circuits.

What is claimed is:

1. A semiconductor integrated circuit device comprising:
a CMOS-based input protection circuit or a CMOS-based output protection circuit constructed of a pair of a P-channel MOS transistor and an N-channel MOS transistor,
wherein a back gate of said P-channel MOS transistor is biased at a voltage higher than a peak voltage of an overshooting input or output signal of said P-channel MOS transistor, or a back gate of said N-channel MOS transistor is biased at a voltage lower than a negative peak voltage of undershooting input or output signal of said N-channel MOS transistor.

2. The semiconductor integrated circuit device according to claim 1, wherein said P-channel MOS transistor is constructed such that a power source potential is applied to a gate and a source thereof, the back gate thereof is biased at a voltage higher than the peak voltage of a potential overshooting of the input signal, and the input signal is supplied to a drain thereof, and
said N-channel MOS transistor is constructed such that a common potential is applied to a gate, a source and the back gate thereof, and the input signal is supplied to a drain thereof.

3. The semiconductor integrated circuit device according to claim 1, wherein said P-channel MOS transistor is constructed such that a power source potential is applied to the gate, the source and the back gate thereof, and the input signal is supplied to the drain thereof, and
said N-channel MOS transistor is constructed such that the common potential is applied to the gate and the source thereof, the back gate thereof is biased at a voltage lower than the negative peak voltage of a potential undershooting of the input signal, and the input signal is supplied to the drain thereof.

4. The semiconductor integrated circuit device according to claim 1, wherein said P-channel MOS transistor is constructed such that the power source potential is applied to the gate and the source thereof, and the back gate thereof is biased at a voltage higher than the peak voltage of a potential overshooting of the input signal, and the input signal is supplied to the drain thereof, and
said N-channel MOS transistor is constructed such that the common potential is applied to the gate and the source thereof, the back gate thereof is biased at a voltage lower than the negative peak voltage of a potential undershooting of the input signal, and the input signal is supplied to the drain thereof.

5. The semiconductor integrated circuit device according to claim 1, wherein said P-channel MOS transistor is constructed such that the power source potential is applied to the source thereof, an output terminal is connected to a drain thereof, and the back gate thereof is biased at a voltage higher than the peak voltage of a potential overshooting of the output terminal, and
said N-channel MOS transistor is constructed such that the common potential is applied to the source and the back gate thereof, and the output terminal is connected to the drain thereof.

6. The semiconductor integrated circuit device according to claim 1, wherein said P-channel MOS transistor is constructed such that the power source potential is applied to the source and the back gate thereof, and the output terminal is connected to the drain thereof, and
said N-channel MOS transistor is constructed such that the common potential is applied to the source thereof, the back gate thereof is biased at a voltage lower than the negative peak voltage of a potential undershooting of the output terminal.

7. The semiconductor integrated circuit device according to claim 1, wherein said P-channel MOS transistor is constructed such that the power source potential is applied to the source thereof, the output terminal is connected to the drain thereof, and the back gate thereof is biased at a voltage higher than the peak voltage of a potential overshooting from the output terminal, and
said N-channel MOS transistor is constructed such that the common potential is applied to the source thereof, the output terminal is connected to the drain thereof, and the back gate thereof is biased at a voltage lower than the negative peak voltage of a potential undershooting of the output terminal.

8. A method of controlling a semiconductor integrated circuit device having a CMOS-based input protection circuit or a CMOS-based output protection circuit constructed of a pair of a P-channel MOS transistor and an N-channel MOS transistor, said method comprising:
a step of biasing a back gate of said P-channel MOS transistor at a voltage higher than a peak voltage of an overshooting of an input signal or an output signal of said P-channel MOS transistor, or biasing a back gate of said N-channel MOS transistor at a voltage lower than a negative peak voltage of an undershooting of the input signal or the output signal.

9. The method of controlling the semiconductor integrated circuit device according to claim 8, further comprising:
a step of, in said P-channel MOS transistor, applying a power source potential to a gate and a source thereof, and inputting the input signal to a drain thereof; and
a step of, in said N-channel MOS transistor, applying a common potential to a gate, a source and the back gate thereof, and inputting the input signal to a drain thereof,
wherein the back gate of said P-channel MOS transistor is biased at a voltage higher than a peak voltage of a potential overshooting of the input signal.

10. The method of controlling the semiconductor integrated circuit device according to claim 8, further comprising:
a step of, in said P-channel MOS transistor, applying the power source potential to the gate, the source and the back gate thereof, and inputting the input signal to the drain thereof; and
a step of, in said N-channel MOS transistor, applying the common potential to the gate and the source thereof, and inputting the input signal to the drain thereof,
wherein the back gate of said N-channel MOS transistor is biased at a voltage lower than the negative peak voltage of a potential undershooting of the input signal.

11. The method of controlling the semiconductor integrated circuit device according to claim 8, further comprising:
a step of, in said P-channel MOS transistor, applying the power source potential to the gate and the source thereof, and inputting the input signal to the drain thereof, and
a step of, in said N-channel MOS transistor, applying the common potential to the gate and the source thereof, and inputting the input signal to the drain thereof,
wherein the back gate of said P-channel MOS transistor is biased at a voltage higher than the peak voltage of a potential overshooting of the input signal, and
wherein the back gate of said N-channel MOS transistor is biased by the voltage lower than the negative peak voltage of a potential undershooting of the input signal.

12. The method of controlling the semiconductor integrated circuit device according to claim 8, further comprising:
a step of, in said P-channel MOS transistor, applying a power source potential to a source thereof, and connecting an output terminal to a drain thereof; and
a step of, in said N-channel MOS transistor, applying a common potential to a source and the back gate thereof, and connecting an output terminal to a drain thereof,
wherein the back gate of said P-channel MOS transistor of said semiconductor integrated circuit device is biased at a voltage higher than the peak voltage of a potential overshooting of the output terminal.

13. The method of controlling the semiconductor integrated circuit device according to claim 8, further comprising:
a step of, in said P-channel MOS transistor, applying the power source potential to the source and the back gate thereof, and connecting an output terminal to the drain thereof; and
a step of, in said N-channel MOS transistor, applying the common potential to the source thereof, and connecting the output terminal to the drain thereof,
wherein the back gate of said N-channel MOS transistor is biased at a voltage lower than the negative peak voltage of a potential undershooting of the output terminal.

14. The method of controlling the semiconductor integrated circuit device according to claim 8, further comprising:
a step of, in said P-channel MOS transistor, applying the power source potential to the source thereof, and connecting an output terminal to the drain thereof; and
a step of, in said N-channel MOS transistor, applying the common potential to the source thereof, and connecting the output terminal to the drain thereof,
wherein the back gate of said P-channel MOS transistor is biased at a voltage higher than the peak voltage of a potential overshooting at the output terminal, and the back gate of said N-channel MOS transistor is biased at a voltage lower than the negative peak voltage of a potential undershooting of the output terminal.
